(19) United States
(12) Patent Application Publication
(10) Pub. No.: US 2025/0226205 A1
(43) Pub. Date: Jul. 10, 2025

(54) METHOD FOR SELECTIVE DEPOSITION ON DIELECTRIC MATERIALS

(71) Applicant: ENTEGRIS, INC., Billerica, MA (US)

(72) Inventors: SungHae Lee, Suwon-si (KR); Montray Leavy, Singapore (SG); Mark Puttock, Worcester (GB)

(21) Appl. No.: 18/403,858

(22) Filed: Jan. 4, 2024

(51) Int. Cl. H01L 21/02

(52) U.S. Cl. CPC H01L 21/0228; H01L 21/02164; H01L 21/0217

(57) ABSTRACT

A method includes forming a structure, and the structure includes a first dielectric layer made of silicon oxide and a second dielectric layer made of silicon nitride. The method further includes performing a selective deposition process for depositing a third dielectric layer made of silicon oxide on the first dielectric layer. Performing the selective deposition process includes performing one or more deposition cycles. Performing a deposition cycle includes introducing a silicon-containing precursor over the structure. The silicon-containing precursor comprises a siloxane material having a chemical formula SiₐH_{b}(CH₃)_{2a+1-b}—O—Si_{c}H_{d}(CH₃)_{2c+1-d}, where a, c=1 or 2, and b, d≤2a+1. Molecules of the silicon-containing precursor are selectively adsorbed on an exposed surface of the first dielectric layer. Performing the deposition cycle further includes introducing an oxygen-containing precursor over the structure. Molecules of the oxygen-containing precursor react with the molecules of the silicon-containing precursor to form a silicon oxide sub-layer of the third dielectric layer.

### TECHNICAL FIELD

This disclosure generally relates to deposition on dielectric materials, and more specifically to selective deposition on dielectric materials.

### BACKGROUND

An integrated circuit is typically formed by the sequential deposition of conductive, semi-conductive, and/or insulative layers on a substrate. As dimensions (e.g., width, pitch, etc.) of semiconductor devices that are formed on the substrate decrease, it becomes more difficult to make features of semiconductor devices by patterning such as dry or wet etching.

### SUMMARY

The present disclosure provides several practical applications and technical advantages that overcome the current technical problems with patterning processes when forming features of semiconductor devices that have reduced dimensions.

The present disclosure allows for forming features with reduced dimensions by selectively forming a dielectric layer on a structure that includes multiple dielectric layers made of different dielectric materials. In some embodiments, the disclosed method allows for depositing a second silicon oxide layer on a structure that includes a first silicon oxide layer and a first silicon nitride layer, such that the second silicon oxide layer is selectively deposited on the first silicon oxide layer. In other embodiments, the disclosed method allows depositing a second silicon nitride layer on a structure that includes a first silicon oxide layer and a first silicon nitride layer, such that the second silicon nitride layer is selectively deposited on the first silicon nitride layer.

The selective deposition may be achieved by choosing appropriate silicon-containing precursors and appropriate inhibitor materials. For a selective deposition of silicon oxide on silicon oxide, a silicon-containing precursor may be chosen such that an activation energy, which leads to chemisorption from physisorption, of the silicon-containing precursor on an exposed surface of silicon oxide is less than an activation energy of the silicon-containing precursor on an exposed surface of silicon nitride, and an inhibitor material may be chosen such that physisorption of the inhibitor material on the exposed surface of silicon nitride is more stable than physisorption of the inhibitor material on the exposed surface of the silicon oxide, where activation energies of the inhibitor material are high enough to reduce or prevent easy chemical bonding at process temperatures. The inhibitor material is configured to be adsorbed on the exposed surface of silicon nitride and protect silicon nitride from processes performed on the exposed surface of the silicon oxide during the selective deposition process.

For a selective deposition of silicon nitride on silicon nitride, a silicon-containing precursor may be chosen such that an activation energy, which leads to chemisorption from physisorption, of the silicon-containing precursor on an exposed surface of silicon nitride is less than an activation energy of the silicon-containing precursor for an exposed surface of silicon oxide, and an inhibitor material may be chosen such that physisorption of the inhibitor material on the exposed surface of silicon oxide is more stable than physisorption of the inhibitor material on the exposed surface of the silicon nitride, where activation energies of the inhibitor material are high enough to reduce or prevent easy chemical bonding at process temperatures. The inhibitor material is configured to be adsorbed on the exposed surface of silicon oxide and protect silicon oxide from processes performed on the exposed surface of the silicon nitride during the selective deposition process.

In one embodiment, a method includes forming a structure. The structure includes a first dielectric layer made of silicon oxide and a second dielectric layer made of silicon nitride. The method further includes performing a selective deposition process for depositing a third dielectric layer made of silicon oxide on the first dielectric layer. Performing the selective deposition process includes performing one or more deposition cycles. Performing a deposition cycle includes introducing a silicon-containing precursor over the structure. The silicon-containing precursor comprises a siloxane material having a chemical formula SiₐH_{b}(CH₃)_{2a+1-b}—O—Si_{c}H_{d}(CH₃)_{2c+1-d}, where a, c=1 or 2, and b, d≤2a+1. Molecules of the silicon-containing precursor are selectively adsorbed on an exposed surface of the first dielectric layer. Performing the deposition cycle further includes introducing an oxygen-containing precursor over the structure. Molecules of the oxygen-containing precursor react with the molecules of the silicon-containing precursor to form a silicon oxide sub-layer of the third dielectric layer. In an embodiment, performing the deposition cycle further includes purging un-adsorbed molecules of the silicon-containing precursor. In an embodiment, performing the deposition cycle further includes purging unreacted molecules of the oxygen-containing precursor. In an embodiment, performing the deposition cycle further includes, before introducing the silicon-containing precursor over the structure, introducing an inhibitor material over the structure, where molecules of the inhibitor material are selectively adsorbed on an exposed surface of the second dielectric layer. In an embodiment, performing the deposition cycle further includes purging un-adsorbed molecules of the inhibitor material. In an embodiment, the inhibitor material includes a material having a chemical formula CₐH_{b}X_{2a+2-b}, where a=1 or 2, b<2a+2, and X═Cl, Br, or I. In an embodiment, the method further includes, after depositing the third dielectric layer, removing adsorbed molecules of the inhibitor material from the second dielectric layer. In an embodiment, the oxygen-containing precursor includes an oxygen-containing gas such as O₂, H₂O, or O₃. In an embodiment, the exposed surface of the first dielectric layer is an OH-terminated surface. In an embodiment, the exposed surface of the second dielectric layer is an NH₂-terminated surface.

In another embodiment, a method includes forming a structure. The structure includes a first dielectric layer made of silicon oxide and a second dielectric layer made of silicon nitride. The method further includes performing a selective deposition process for depositing a third dielectric layer made of silicon nitride on the second dielectric layer. Performing the selective deposition process includes performing one or more deposition cycles. Performing a deposition cycle includes introducing a silicon-containing precursor over the structure. The silicon-containing precursor comprises a material having a chemical formula SiₐH_{b}X_{2a+2-b}, where a is 1 or 2, b<2a+2 and X═Br or I. Molecules of the silicon-containing precursor are selectively adsorbed on an exposed surface of the second dielectric layer. Performing the deposition cycle further includes introducing a nitrogen-containing precursor over the structure. Molecules of the nitrogen-containing precursor react with the molecules of the silicon-containing precursor to form a silicon nitride sub-layer of the third dielectric layer. In an embodiment, performing the deposition cycle further includes purging un-adsorbed molecules of the silicon-containing precursor. In an embodiment, performing the deposition cycle further includes purging unreacted molecules of the nitrogen-containing precursor. In an embodiment, performing the deposition cycle further includes, before introducing the silicon-containing precursor over the structure, introducing an inhibitor material over the structure, where molecules of the inhibitor material are selectively adsorbed on an exposed surface of the first dielectric layer. In an embodiment, performing the deposition cycle further includes purging un-adsorbed molecules of the inhibitor material. In an embodiment, the inhibitor material includes a material having a chemical formula R₁—O—R₂, or R₁—NH₂, where R₁ is CH₃— or CH₃CH₂— and R₂ is CH₃— or CH₃CH₂—. In an embodiment, the method further comprises, after depositing the third dielectric layer, removing adsorbed molecules of the inhibitor material from the second dielectric layer. In an embodiment, the nitrogen-containing precursor includes a nitrogen-containing gas such as N₂ or NH₃. In an embodiment, the exposed surface of the first dielectric layer is an OH-terminated surface. In an embodiment, the exposed surface of the second dielectric layer is an NH₂-terminated surface.

Certain embodiments of this disclosure may include some, all, or none of these advantages. These advantages and other features will be more clearly understood from the following detailed description taken in conjunction with the accompanying drawings and claims.

### BRIEF DESCRIPTION OF FIGURES

To assist in understanding the present disclosure, reference is now made to the following description taken in conjunction with the accompanying drawings, in which:

FIGS. 1A through 1C illustrate cross-sectional views of intermediate stages for manufacturing a semiconductor structure, according to an illustrative embodiment of this disclosure;

FIGS. 2A through 2H illustrate cross-sectional views of intermediate stages for selectively depositing dielectric layers on a semiconductor structure, according to an illustrative embodiment of this disclosure;

FIGS. 3A through 3H illustrate cross-sectional views of intermediate stages for selectively depositing dielectric layers on a semiconductor structure, according to an illustrative embodiment of this disclosure;

FIG. 4 illustrates various adsorption energies of various silicon-containing precursors for adsorption on an OH-terminated surface of the silicon oxide and an NH₂-terminated surface of silicon nitride, according to an illustrative embodiment of this disclosure;

FIG. 5 is a flowchart of a process for depositing a dielectric layer over a semiconductor structure, according to an illustrative embodiment of this disclosure; and

FIG. 6 is a flowchart of a process for depositing a dielectric layer over a semiconductor structure, according to an illustrative embodiment of this disclosure.

### DETAILED DESCRIPTION

It should be understood at the outset that, although example implementations of embodiments of the disclosure are illustrated below, the present disclosure may be implemented using any number of techniques, whether currently known or not. The present disclosure should in no way be limited to the example implementations, drawings, and techniques illustrated below. Additionally, the drawings are not necessarily drawn to scale.

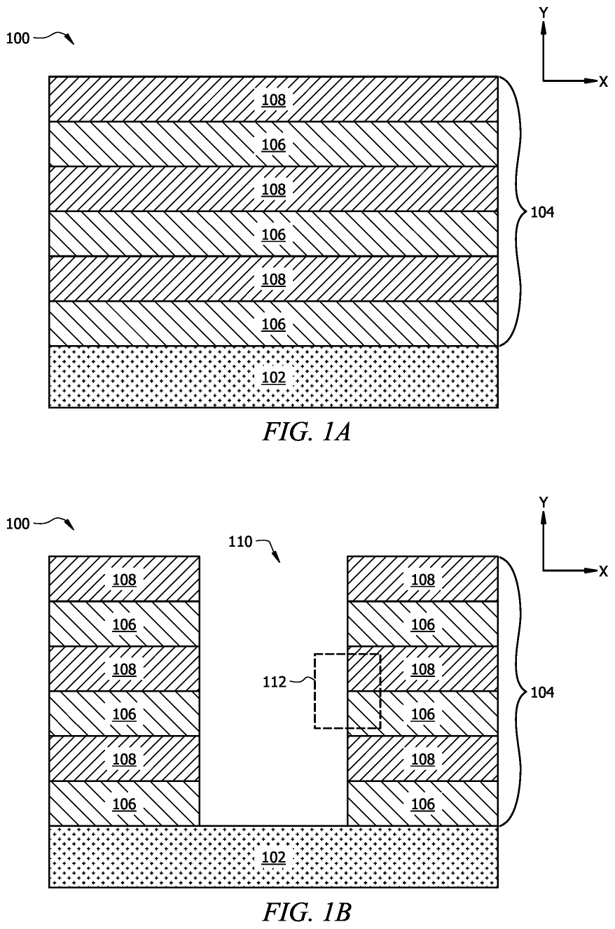

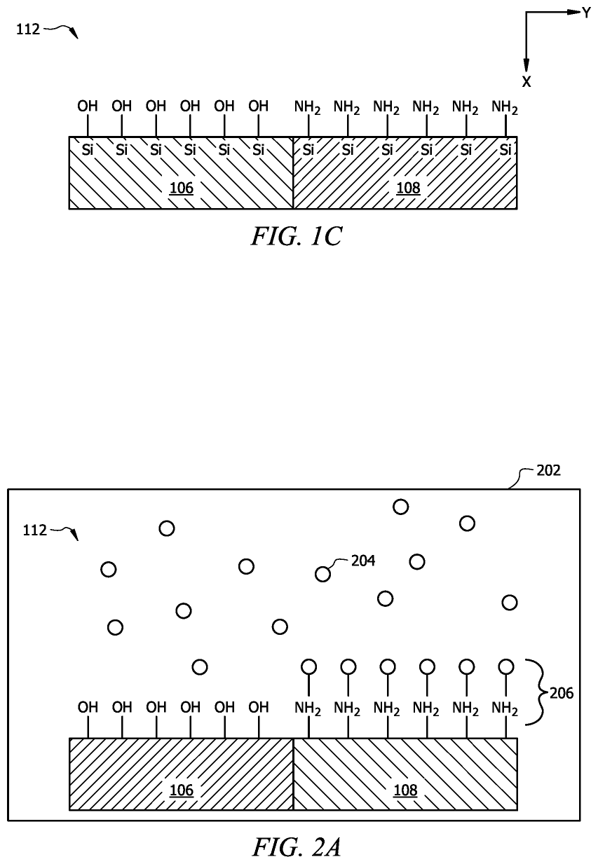

FIGS. 1A through 1C illustrate cross-sectional views of intermediate stages for manufacturing a semiconductor structure 100, according to an illustrative embodiment of this disclosure. In FIG. 1A, a stack 104 of dielectric layers 106 and 108 is formed over a substrate 102. The substrate 102 may be a semiconductor substrate and may comprise a semiconductor material, such as silicon, germanium, silicon germanium, or the like. In some embodiments, the substrate 102 may comprise a silicon-on-insulator (SOI) structure. The substrate 102 may be an n-doped substrate, a p-doped substrate, a gradient-doped substrate, or the like. In other embodiments, the substrate 102 may be an insulating substrate or a conductive substrate.

The stack 104 comprises the dielectric layers 106 and the dielectric layers 108 that are alternately formed on an upper surface of the substrate 102. The dielectric layer 106 and the dielectric layer 108 may be formed of different dielectric materials. In the illustrated embodiment, the dielectric layer 106 is formed of an oxide material (e.g., SiOₓ) and the dielectric layer 108 is formed of a nitride material (e.g., SiₓN_{y}). The SiOₓ may be referred to as silicon oxide and may be a stoichiometric silicon oxide (SiO₂), an oxygen-deficient silicon oxide, or an oxygen-rich silicon oxide. The SiₓN_{y} may be referred to as silicon nitride and may be a stoichiometric silicon nitride (Si₃N₄), a nitrogen-deficient silicon nitride, or a nitrogen-rich silicon nitride. Each of the dielectric layers 106 and 108 may be formed using atomic layer deposition (ALD), chemical vapor deposition (CVD), plasma-enhanced ALD, plasma-enhanced CVD, a combination thereof, or the like.

In FIG. 1B, one or more openings 110 are formed in the stack 104. In some embodiments, the stack 104 may be patterned using suitable photolithography and etching methods. For example, a patterned mask (e.g., photoresist) may be formed over the stack 104 and exposed portions of the stack 104 are removed using one or more etching processes. The one or more etching processes may comprise one or more wet etching processes, one or more dry etching processes, or the like. In some embodiments, the semiconductor structure 100 as shown in FIG. 1B may be an intermediate structure during fabrication of a three-dimensional (3D) vertical NAND (V-NAND) device.

FIG. 1C illustrates a magnified view of a region 112 of the semiconductor structure 100 as shown in FIG. 1B. In some embodiments when the dielectric layer 106 is made of silicon oxide, an exposed surface (illustrated as an upper surface in FIG. 1C) may comprise surface bonds Si—OH. Such exposed surface may be also referred to as an OH-terminated surface. In some embodiments when the dielectric layer 108 is made of silicon nitride, an exposed surface (illustrated as an upper surface in FIG. 1C) of the dielectric layer 108 may comprise surface bonds Si—NH₂. Such exposed surface may be also referred to as an NH₂-terminated surface.

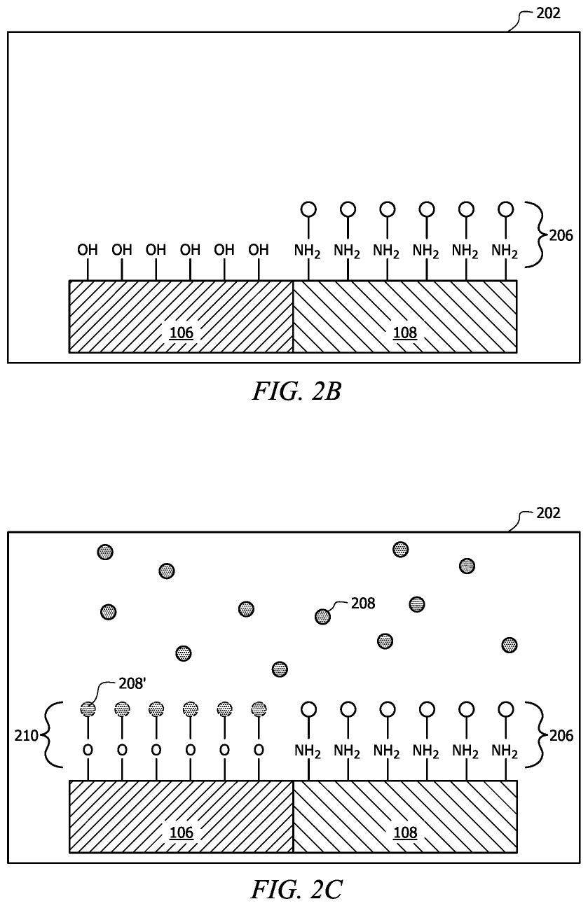

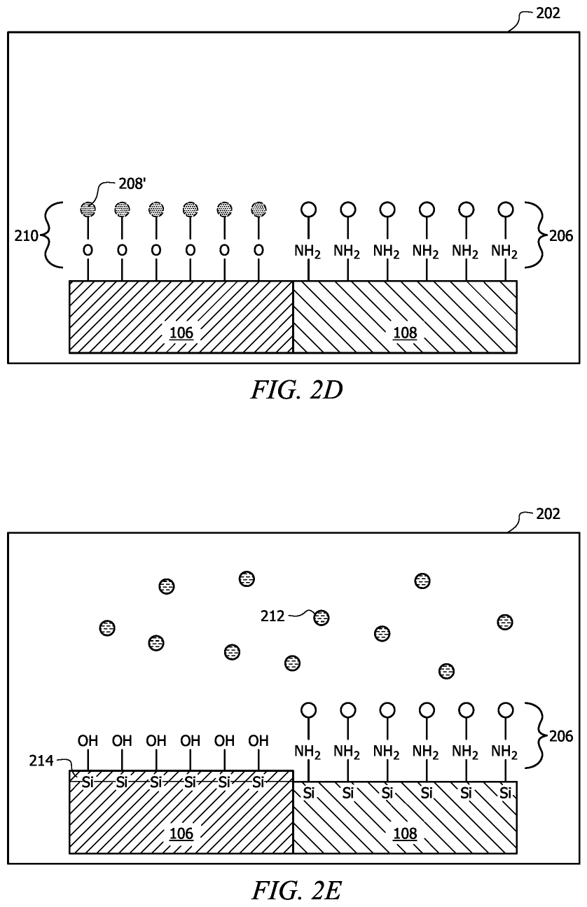

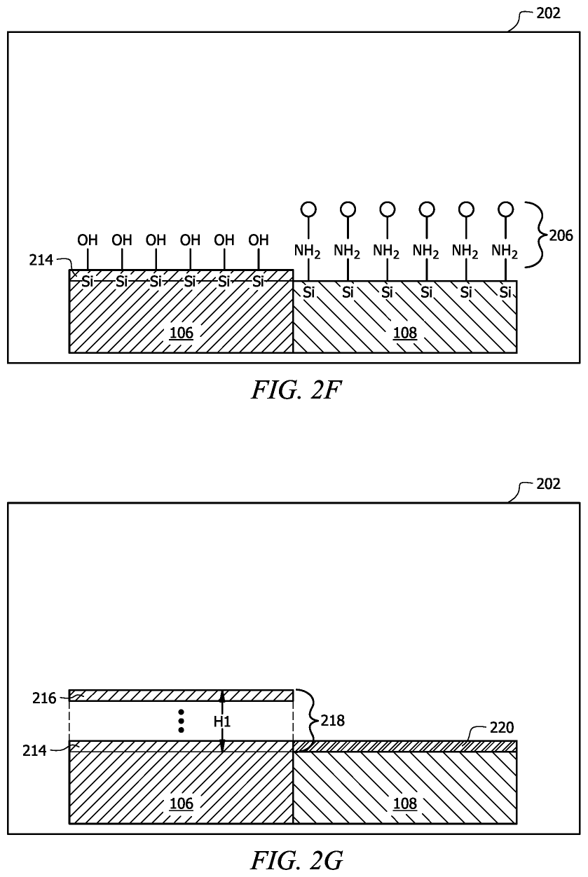

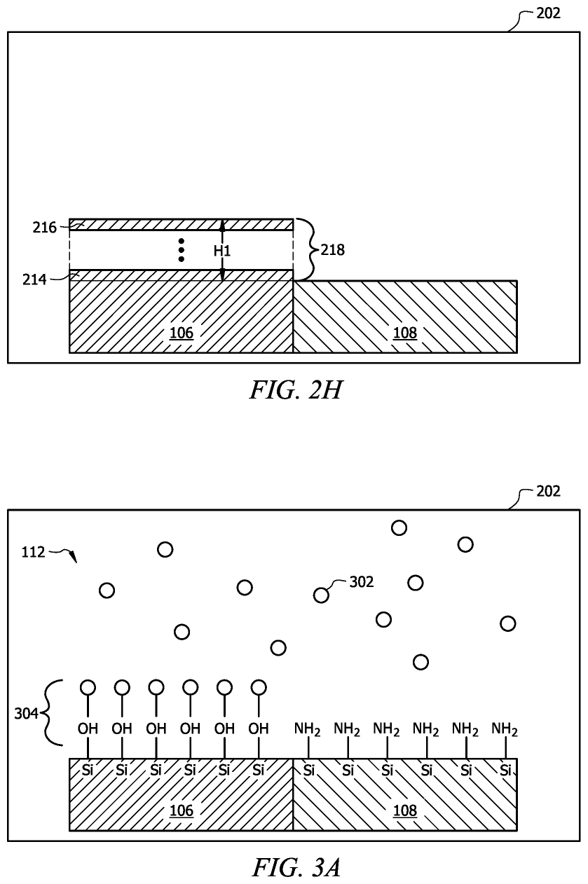

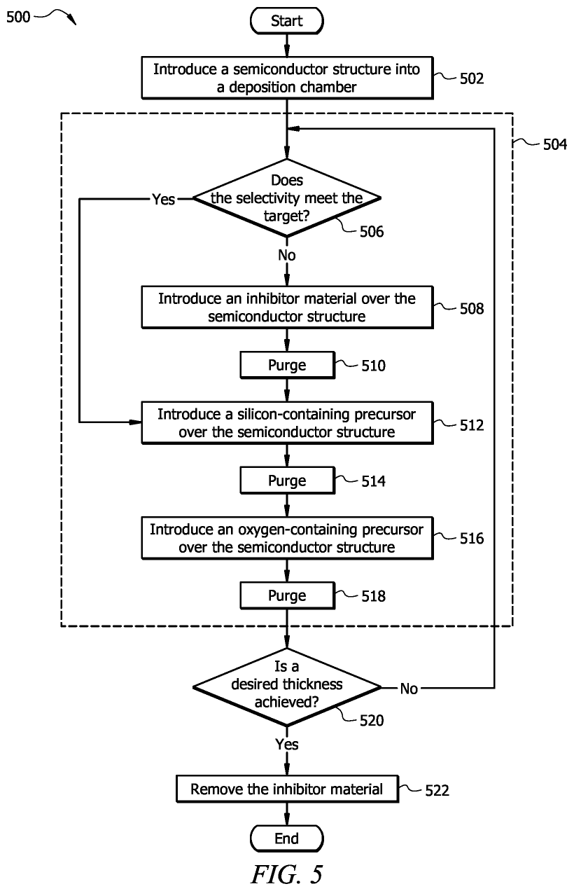

FIGS. 2A through 2H illustrate cross-sectional views of intermediate stages for selectively depositing dielectric layers on the semiconductor structure 100 (see FIG. 1B), according to an illustrative embodiment of this disclosure. For the clarity of presentation, only processes performed on the region 112 (see FIG. 1C) of the semiconductor structure 100 are shown in FIGS. 2A through 2H. In the illustrated embodiment, the dielectric layer 218 (see FIG. 2H) comprising silicon oxide is selectively deposited on the dielectric layers 106 of the semiconductor structure 100. FIG. 5 illustrates a flowchart of a process 500 of FIGS. 2A through 2H for selectively depositing the dielectric layer 218 on the dielectric layer 106 of the semiconductor structure 100, according to an illustrative embodiment of this disclosure.

Referring to FIGS. 2A and 5, in step 502, the semiconductor structure 100 (see FIG. 1B) is introduced into a deposition chamber 202. After introducing the semiconductor structure 100 into the deposition chamber 202, in step 504, a deposition cycle is performed on the semiconductor structure 100. In some embodiments, the deposition cycle is a deposition cycle of an ALD process and comprises steps 506, 508, 510, 512, 514, 516 and 518. As described below in greater detail, an inhibitor material 204 (see FIG. 2A), a silicon-containing precursor 208 (see FIG. 2C), and an oxygen-containing precursor 212 (see FIG. 2E) may be introduced into the deposition chamber 202 at each deposition cycle.

To achieve the desired selective deposition, the silicon-containing precursor 208 may be chosen to have a lower activation energy (Ea) on the OH-terminated surface of the silicon oxide than on the NH₂-terminated surface of silicon nitride. Due to high selectivity to the OH-terminated surface of silicon oxide, molecules of the silicon-containing precursor 208 are chemically adsorbed to the OH-terminated surface of the dielectric layer 106 and are not chemically adsorbed on an NH₂-terminated surface of the dielectric layer 108. In certain embodiments, the selectivity achieved by the silicon-containing precursor 208 may be less than a desired target selectivity, which depends on design characteristic of a device that is formed from the semiconductor structure 100 (see FIG. 1B). In such embodiments, before introducing the silicon-containing precursor 208 into the deposition chamber 202, the inhibitor material 204 may be introduced into the deposition chamber 202. The inhibitor material 204 may be chosen such that it is selective to the NH₂-terminated surface of the dielectric layer 108. The inhibitor material 204 is configured to be physically adsorbed on the exposed surface of the dielectric layer 108 and protects the dielectric layer 108 from subsequent process steps that are performed on the dielectric layer 106.

Referring further to FIGS. 2A and 5, in step 506, it is determined whether a selectivity of the chosen silicon-containing precursor 208 meets the target selectivity. In response to determining at step 506 that the selectivity of the chosen silicon-containing precursor 208 does not meets the target selectivity, the process 500 proceeds to step 508. In step 508, the inhibitor material 204 is introduced into the deposition chamber 202 over the semiconductor structure 100. The inhibitor material 204 is configured to be physically adsorbed on the exposed surface of the dielectric layer 108 and protects the dielectric layer 108 from subsequent process steps that are performed on the dielectric layer 106. In the illustrated embodiment, the subsequent process steps include forming a silicon-containing precursor layer 210 on the dielectric layer 106 that is performed by introducing the silicon-containing precursor 208 in the deposition chamber 202 and an oxidation process that is performed by introducing the oxygen-containing precursor 212 into the deposition chamber 202.

The inhibitor material 204 may be chosen such that it is selective to the NH₂-terminated surface of silicon nitride. To achieve high selectivity to the NH₂-terminated surface of silicon nitride compared to the OH-terminated surface of silicon oxide, the inhibitor material 204 is chosen such that molecules of the inhibitor material 204 have a lower physisorption energy (E_{ads}) on the NH₂-terminated surface of silicon nitride compared to the OH-terminated surface of silicon oxide, with molecules having a greater physisorption energy difference (ΔE_{ads}) having a greater selectivity compared to molecules having a lower physisorption energy difference (ΔE_{ads}). Furthermore, the inhibitor material 204 is chosen such that molecules of the inhibitor material 204 have large activation energies (Ea) to prevent bond formations with both the OH-terminated surface of silicon oxide and NH₂-terminated surface of silicon nitride. In certain embodiments, the inhibitor material 204 may comprise a material having a chemical formula CₐH_{b}X_{2a+2-b}, where a=1 or 2, b<2a+2, and X═Cl, Br, or I.

TABLE I illustrates physisorption energies (E_{ads}) and activation energies (Ea) of exemplary inhibitor materials 204 such as a material having a chemical formula CH₂Cl₂ and as a material having a chemical formula CH₂I₂. The material having the chemical formula CH₂Cl₂ has a physisorption energy difference (ΔE_{ads}) between the OH-terminated surface of silicon oxide and the NH₂-terminated surface of silicon nitride of 0.2 eV that implies that CH₂Cl₂ is more selective to the NH₂-terminated surface of silicon nitride than to the OH-terminated surface of silicon oxide. The material having the chemical formula CH₂I₂ has a physisorption energy difference (ΔE_{ads}) between the OH-terminated surface of silicon oxide and the NH₂-terminated surface of silicon nitride of 0.24 eV that implies that CH₂I₂ is more selective to the NH₂-terminated surface of silicon nitride than to the OH-terminated surface of silicon oxide. Since the absolute value of the physisorption energy difference (ΔE_{ads}) for CH₂I₂ is greater than the absolute value of the physisorption energy difference (ΔE_{ads}) for CH₂Cl₂, CH₂I₂ has a better selectivity to the NH₂-terminated surface of silicon nitride than CH₂Cl₂.

TABLE I
Physisorption energies (E_{ads}) and activation energies (Eₐ) of exemplary
silicon-containing precursors and exemplary inhibitor materials

| | | SiO₂ (Si—OH) | | Si₃N₄ (Si—NH₂) | | |
|---|---|---|---|---|---|---|
| | | E_{ads} | | E_{ads} | | |
| | | (eV) | Eₐ(eV) | (eV) | Eₐ(eV) | ΔEₐ(eV) |
| Si- | TMDSO (SiH(CH₃)₂—O—SiH(CH₃)₂) | −0.48 | 0.77 | −0.48 | 1.75 | −0.98 |
| containing | SiH₃—O—SiH(CH₃)₂ | −0.39 | 0.40 | −0.37 | 1.67 | −1.27 |
| precursor | SiH₂I₂ | −0.25 | 1.53 | −0.26 | 0.78 | 0.75 |

| | | E_{ads} | | E_{ads} | | |
|---|---|---|---|---|---|---|
| | | (eV) | Eₐ(eV) | (eV) | Eₐ(eV) | ΔE_{ads}(eV) |
| Inhibitor | CH₃—O—H₃ | −0.47 | 2.71 | −0.16 | 2.14 | −0.31 |
| material | CH₃NH₂ | −0.49 | 2.30 | −0.27 | 2.83 | −0.22 |
| | CH₂Cl₂ | −0.14 | 2.10 | −0.34 | 2.70 | 0.20 |
| | CH₂I₂ | −0.25 | 1.93 | −0.49 | 2.38 | 0.24 |

Due to high selectivity to the NH₂-terminated surface of silicon nitride, molecules of the inhibitor material 204 are physically adsorbed to the NH₂-terminated surface of the dielectric layer 108 and are not physically adsorbed on the dielectric layer 106. In certain embodiments, adsorbed molecules of the inhibitor material 204 form an inhibitor material layer 206 on the dielectric layer 108.

Referring to FIGS. 2B and 5, in step 510, a first purge process is performed to remove un-adsorbed molecules of the inhibitor material 204 (see FIG. 2A) from the deposition chamber 202. In certain embodiments, an inert gas (e.g., He, Ar, Xe, or the like) or N₂ may be introduced into the deposition chamber 202 to remove the un-adsorbed molecules of the inhibitor material 204 (see FIG. 2A) from the deposition chamber 202.

Referring to FIGS. 2C and 5, in response to determining at step 506 that the selectivity of the chosen silicon-containing precursor 208 meets the target selectivity or after performing step 510, the process 500 proceeds to step 512. In step 512, a silicon-containing precursor 208 is introduced into the deposition chamber 202 over the semiconductor structure 100. To achieve the desired selective deposition, the silicon-containing precursor 208 is chosen to have a lower activation energy (Ea) on the OH-terminated surface of the silicon oxide than on the NH₂-terminated surface of silicon nitride. In certain embodiments, the silicon-containing precursor 208 comprises a siloxane material having a chemical formula SiₐH_{b}(CH₃)_{2a+1-b}—O—Si_{c}H_{d}(CH₃)_{2c+1-d}, where a, c=1 or 2, and b, d≤2a+1.

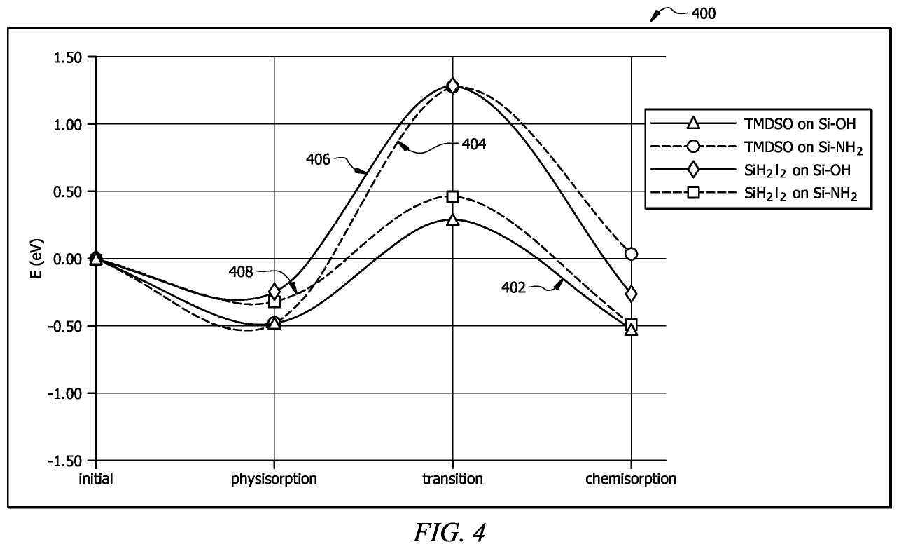

FIG. 4 illustrates various adsorption energies (e.g., physisorption energy and chemisorption energy) of various silicon-containing precursors for adsorption on the OH-terminated surface of the silicon oxide and the NH₂-terminated surface of silicon nitride, according to an illustrative embodiment of this disclosure. The curve 402 shows adsorption energies (e.g., physisorption energy and chemisorption energy) of tetramethyldisiloxane (TMDSO) for adsorption on the OH-terminated surface of silicon oxide. The curve 404 shows adsorption energies (e.g., physisorption energy and chemisorption energy) of tetramethyldisiloxane (TMDSO) for adsorption on the NH₂-terminated surface of silicon nitride.

TABLE I further illustrates physisorption energies (E_{ads}) and activation energies (Ea) of exemplary silicon-containing precursors 208 such as tetramethyldisiloxane (TMDSO) having a symmetric structure with a chemical formula SiH(CH₃)₂—O—SiH(CH₃)₂ and a siloxane material having an asymmetric structure with a chemical formula SiH₃—O—SiH(CH₃)₂. TDMSO has an activation energy difference (ΔEₐ) between the OH-terminated surface of silicon oxide and the NH₂-terminated surface of silicon nitride of −0.98 eV that implies that TDMSO is more selective to the OH-terminated surface of silicon oxide than the NH₂-terminated surface of silicon nitride. The siloxane material with the chemical formula SiH₃—O—SiH(CH₃)₂ has an activation energy difference (ΔEₐ) between the OH-terminated surface of silicon oxide and the NH₂-terminated surface of silicon nitride of-1.27 eV that implies that SiH₃—O-SiH(CH₃)₂ is more selective to the OH-terminated surface of silicon oxide than the NH₂-terminated surface of silicon nitride. Since the absolute value of the activation energy difference (ΔEₐ) for SiH₃—O—SiH(CH₃)₂ is greater than the absolute value of the activation energy difference (ΔEₐ) for TMDSO, SiH₃—O—SiH(CH₃)₂ has a better selectivity to the OH-terminated surface of silicon oxide than TMDSO.

Due to high selectivity to the OH-terminated surface of silicon oxide, molecules of the silicon-containing precursor 208 are chemically adsorbed to the OH-terminated surface of the dielectric layer 106 and are not chemically adsorbed on an NH₂-terminated surface of the dielectric layer 108. In certain embodiments, the chemical adsorption transforms the molecules of the silicon-containing precursor 208 into adsorbed molecules 208′. In such embodiments, the adsorbed molecules 208′ of the silicon-containing precursor 208 form a silicon-containing precursor layer 210 on the dielectric layer 106. The adsorbed molecules 208′ have a structure of un-adsorbed molecules of the silicon-containing precursor 208 with a ligand or an H atom being dissociated.

Referring to FIGS. 2D and 5, in step 514, a second purge process is performed to remove un-adsorbed molecules of the silicon-containing precursor 208 (see FIG. 2C) from the deposition chamber 202. In certain embodiments, an inert gas (e.g., He, Ar, Xe, or the like) or N₂ may be introduced into the deposition chamber 202 to remove the un-adsorbed molecules of the silicon-containing precursor 208 (see FIG. 2C) from the deposition chamber 202.

Referring to FIGS. 2E and 5, in step 516, an oxygen-containing precursor 212 is introduced into the deposition chamber 202 over the semiconductor structure 100. The oxygen-containing precursor 212 may comprise an oxygen-containing gas such as O₂, H₂O, O₃, or the like in vacuum or plasma environment. Molecules of the oxygen-containing precursor 212 react with adsorbed molecules 208′ of the silicon-containing precursor 208 that are present in the silicon-containing precursor layer 210 (see FIG. 2D) to form a dielectric layer 214 comprising silicon oxide. The inhibitor material layer 206 protects the dielectric layer 108 from oxidation due to the oxygen-containing precursor 212.

Referring to FIGS. 2F and 5, in step 518, a third purge process is performed to remove unreacted molecules of the oxygen-containing precursor 212 (see FIG. 2E) and volatile reaction byproducts from the deposition chamber 202. In certain embodiments, an inert gas (e.g., He, Ar, Xe, or the like) or N₂ may be introduced into the deposition chamber 202 to remove the unreacted molecules of the oxygen-containing precursor 212 (see FIG. 2E) and the volatile reaction byproducts from the deposition chamber 202.

Referring to FIGS. 2G and 5, the deposition cycle described above with reference to steps 506 through 518 and FIGS. 2A through 2F, may be repeated one or more times until it is determined, in step 520, that a desired thickness H1 of the deposited dielectric layer 218 is achieved. In the illustrated embodiment, the deposited dielectric layer 218 comprises the dielectric layers 214 through 216, with the dielectric layer 216 being an uppermost dielectric layer of the deposited dielectric layer 218. The dielectric layers 214 through 216 may be also referred to as sub-layers of the deposited dielectric layer 218. In certain embodiments, molecules of the oxygen-containing precursor 212 (see FIG. 2E) introduced into the deposition chamber 202 during various deposition cycles may react with molecules of the inhibitor material 204 (see FIG. 2A) that are present in the inhibitor material layer 206 (see FIG. 2F) to form an oxidized inhibitor material layer 220. In other embodiments, the inhibitor material layer 206 (see FIG. 2F) may remain unoxidized.

Referring to FIGS. 2H and 5, in step 522, the unoxidized inhibitor material layer 206 (see FIG. 2F) or the oxidized inhibitor material layer 220 (see FIG. 2G) is removed to expose the dielectric layer 108. In certain embodiments, the removal process may comprise one or more etching process, such as one or more wet etching processes, one or more dry etching processes, or the like. The one or more etching process may comprise one or more etchants that are selective to the unoxidized inhibitor material of the unoxidized inhibitor material layer 206 (see FIG. 2F) or the oxidized inhibitor material of the oxidized inhibitor material layer 220 (see FIG. 2G).

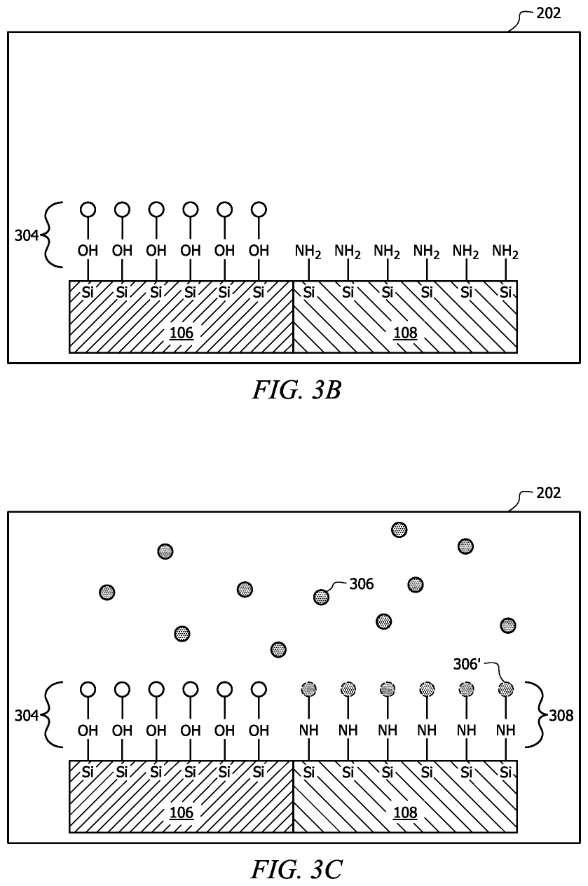

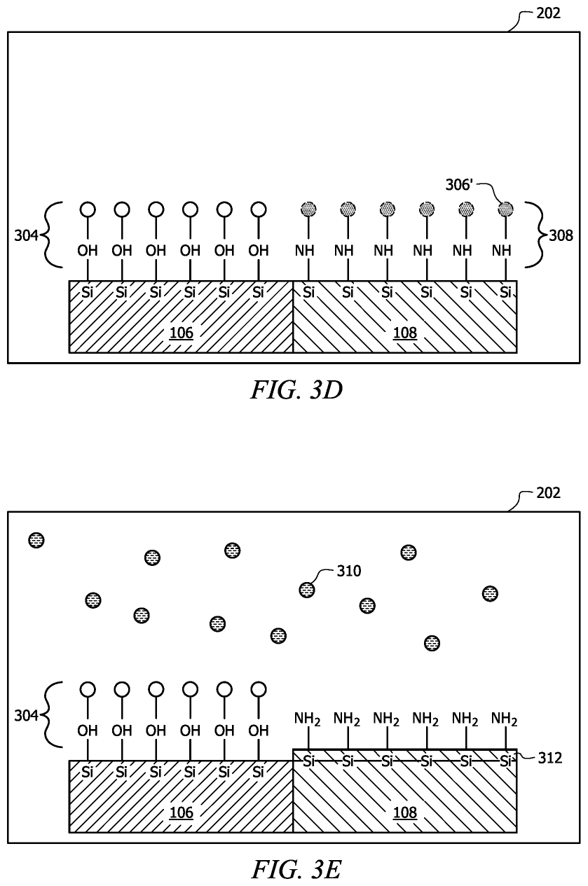

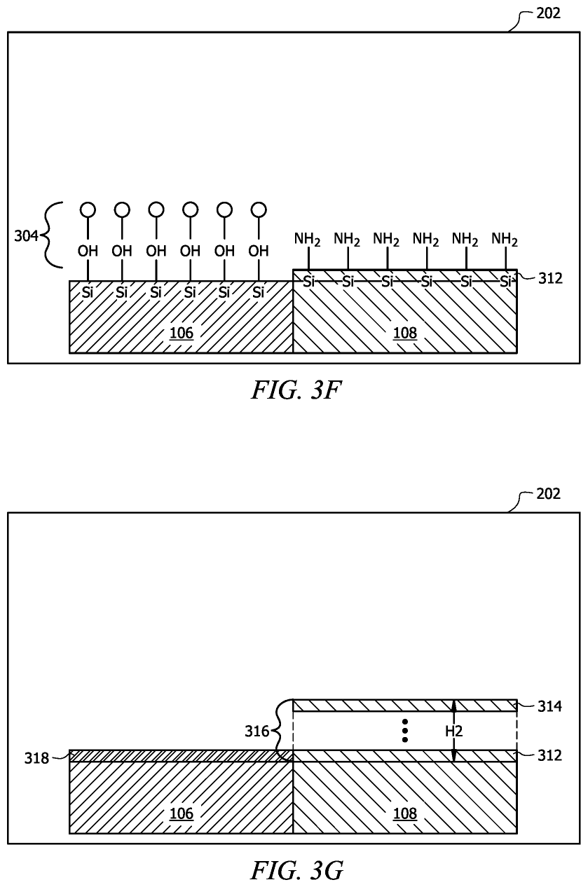

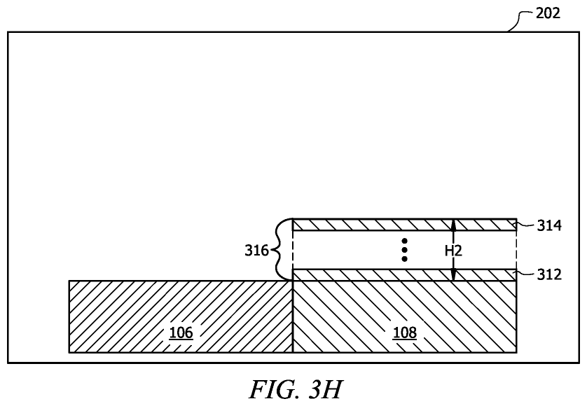

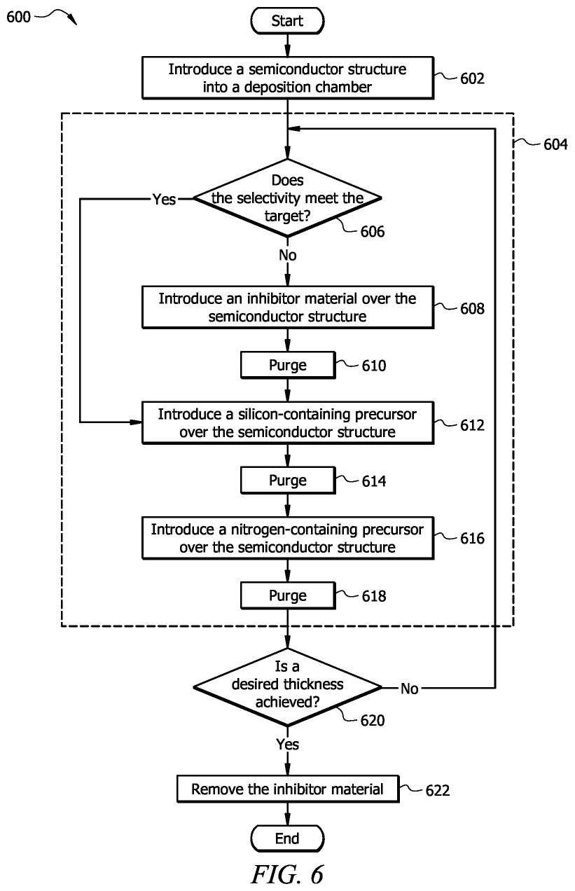

FIGS. 3A through 3H illustrate cross-sectional views of intermediate stages for selectively depositing dielectric layers on the semiconductor structure 100 (see FIG. 1B), according to an illustrative embodiment of this disclosure. For the clarity of presentation, only processes performed on the region 112 (see FIG. 1C) of the semiconductor structure 100 are shown in FIGS. 3A through 3H. In the illustrated embodiment, the dielectric layer 316 (see FIG. 3H) comprising silicon nitride is selectively deposited on the dielectric layers 108 of the semiconductor structure 100. FIG. 6 illustrates a flowchart of a process 600 of FIGS. 3A through 3H for selectively depositing the dielectric layer 316 on the dielectric layer 108 of the semiconductor structure 100, according to an illustrative embodiment of this disclosure.

Referring to FIGS. 3A and 6, in step 602, the semiconductor structure 100 (see FIG. 1B) is introduced into a deposition chamber 202. After introducing the semiconductor structure 100 into the deposition chamber 202, in step 604, a deposition cycle is performed on the semiconductor structure 100. In some embodiments, the deposition cycle is a deposition cycle of an ALD process and comprises steps 606, 608, 610, 612, 614, 616 and 618. As described below in greater detail, an inhibitor material 302 (see FIG. 3A), a silicon-containing precursor 306 (see FIG. 3C), and a nitrogen-containing precursor 310 (see FIG. 3E) may be introduced into the deposition chamber 202 at each deposition cycle.

To achieve the desired selective deposition, the silicon-containing precursor 306 may be chosen to have a lower activation energy (Eₐ) on the NH₂-terminated surface of silicon nitride than on the OH-terminated surface of the silicon oxide. Due to high selectivity to the NH₂-terminated surface of silicon nitride, molecules of the silicon-containing precursor 306 are chemically adsorbed to the NH₂-terminated surface of the dielectric layer 108 and are not chemically adsorbed on an OH-terminated surface of the dielectric layer 106. In certain embodiments, the selectivity achieved by the silicon-containing precursor 306 may be less than a desired target selectivity, which depends on design characteristic of a device that is formed from the semiconductor structure 100 (see FIG. 1B). In such embodiments, before introducing the silicon-containing precursor 306 into the deposition chamber 202, the inhibitor material 302 may be introduced into the deposition chamber 202. The inhibitor material 302 may be chosen such that it is selective to the OH-terminated surface of the dielectric layer 106. The inhibitor material 302 is configured to be physically adsorbed on the exposed surface of the dielectric layer 106 and protects the dielectric layer 106 from subsequent process steps that are performed on the dielectric layer 108.

Referring further to FIGS. 3A and 6, in step 606, it is determined whether a selectivity of the chosen silicon-containing precursor 306 meets the target selectivity. In response to determining at step 606 that the selectivity of the chosen silicon-containing precursor 306 does not meets the target selectivity, the process 600 proceeds to step 608. In step 608, the inhibitor material 302 is introduced into the deposition chamber 202 over the semiconductor structure 100. The inhibitor material 302 is configured to be physically adsorbed on the exposed surface of the dielectric layer 106 and protects the dielectric layer 106 from subsequent process steps that are performed on the dielectric layer 108. In the illustrated embodiment, the subsequent process steps include forming a silicon-containing precursor layer 308 (see FIG. 3C) on the dielectric layer 108 that is performed by introducing the silicon-containing precursor 306 in the deposition chamber 202 and a nitridation process that is performed by introducing the nitrogen-containing precursor 310 (see FIG. 3E) into the deposition chamber 202.

The inhibitor material 302 may be chosen such that it is selective to the OH-terminated surface of silicon oxide. To achieve high selectivity to the OH-terminated surface of silicon oxide compared to the NH₂-terminated surface of silicon nitride, the inhibitor material 302 is chosen such that molecules of the inhibitor material 302 have a lower physisorption energy (E_{ads}) on the OH-terminated surface of silicon oxide compared to the NH₂-terminated surface of silicon nitride, with molecules having a greater physisorption energy difference (ΔE_{ads}) having a greater selectivity compared to molecules having a lower physisorption energy difference (ΔE_{ads}). Furthermore, the inhibitor material 302 is chosen such that molecules of the inhibitor material 302 have a large activation energy (Eₐ) to prevent a bond formation with the OH-terminated surface of silicon oxide. In certain embodiments, the inhibitor material 302 may comprise a material having a formula R₁—O—R₂, or R₁—NH₂, where R₁ comprises CH₃— or CH₃CH₂—, and R₂ comprises CH₃— or CH₃CH₂—.

TABLE I further illustrates physisorption energies (E_{ads}) and activation energies (Eₐ) of exemplary inhibitor materials 302 such as a material having a chemical formula CH₃—O—CH₃ and a material having a chemical formula CH₃NH₂. The material having the chemical formula CH₃—O—CH₃ has a physisorption energy difference (ΔE_{ads}) between the OH-terminated surface of silicon oxide and the NH₂-terminated surface of silicon nitride of-0.31 eV that implies that CH₃—O—CH₃ is more selective to the OH-terminated surface of silicon oxide than to the NH₂-terminated surface of silicon nitride. The material having the chemical formula CH₃NH₂ has a physisorption energy difference (ΔE_{ads}) between the OH-terminated surface of silicon oxide and the NH₂-terminated surface of silicon nitride of-0.22 eV that implies that CH₃NH₂ is more selective to the OH-terminated surface of silicon oxide than to the NH₂-terminated surface of silicon nitride. Since the absolute value of the physisorption energy difference (ΔE_{ads}) for CH₃—O—CH₃ is greater than the absolute value of the physisorption energy difference (ΔE_{ads}) for CH₃NH₂, CH₃—O—CH₃ has a better selectivity to the OH-terminated surface of silicon oxide than CH₃NH₂.

Due to high selectivity to the OH-terminated surface of silicon oxide, molecules of the inhibitor material 302 are physically adsorbed to the OH-terminated surface of the dielectric layer 106 and are not physically adsorbed on the dielectric layer 108. In certain embodiments, adsorbed molecules of the inhibitor material 302 form an inhibitor material layer 304 on the dielectric layer 106.

Referring to FIGS. 3B and 6, in step 610, a first purge process is performed to remove un-adsorbed molecules of the inhibitor material 302 (see FIG. 3A) from the deposition chamber 202. In certain embodiments, an inert gas (e.g., He, Ar, Xe, or the like) or N₂ may be introduced into the deposition chamber 202 to remove the un-adsorbed molecules of the inhibitor material 302 (see FIG. 3A) from the deposition chamber 202.

Referring to FIGS. 3C and 6, in response to determining at step 606 that the selectivity of the chosen silicon-containing precursor 306 meets the target selectivity or after performing step 610, the process 600 proceeds to step 612. In step 612, a silicon-containing precursor 306 is introduced into the deposition chamber 202 over the semiconductor structure 100. To achieve the desired selective deposition, the silicon-containing precursor 306 is chosen to have a lower activation energy (Eₐ) on the NH₂-terminated surface of silicon nitride than on the OH-terminated surface of the silicon oxide. In certain embodiments, the silicon-containing precursor 306 may comprise a material having a chemical formula SiₐH_{b}X_{2a+2-b}, where a is 1 or 2, b<2a+2, and X═Br or I.

FIG. 4 further illustrates various adsorption energies (e.g., physisorption energy and chemisorption energy) of an exemplary silicon-containing precursor 306 for adsorption on the OH-terminated surface of the silicon oxide and the NH₂-terminated surface of silicon nitride, according to an illustrative embodiment of this disclosure. The curve 406 shows adsorption energies (e.g., physisorption energy and chemisorption energy) of SiH₂I₂ for adsorption on the OH-terminated surface of silicon oxide. The curve 408 shows adsorption energies (e.g., physisorption energy and chemisorption energy) of SiH₂I₂ for adsorption on the NH₂-terminated surface of silicon nitride.

TABLE I further illustrates a physisorption energy (E_{ads}) and an activation energy (Eₐ) of an exemplary silicon-containing precursor 306 such as SiH₂I₂. SiH₂I₂ has an activation energy difference (ΔEₐ) between the OH-terminated surface of silicon oxide and the NH₂-terminated surface of silicon nitride of 0.78 eV that implies that SiH₂I₂ is more selective to the NH₂-terminated surface of silicon nitride than to the OH-terminated surface of silicon oxide.

Due to high selectivity to the NH₂-terminated surface of silicon nitride, molecules of the silicon-containing precursor 306 are chemically adsorbed to the NH₂-terminated surface of the dielectric layer 108 and are not chemically adsorbed on an OH-terminated surface of the dielectric layer 106. In certain embodiments, the chemical adsorption transforms the molecules of the silicon-containing precursor 306 into adsorbed molecules 306′. In such embodiments, the adsorbed molecules 306′ of the silicon-containing precursor 306 form a silicon-containing precursor layer 308 on the dielectric layer 106. The adsorbed molecules 306′ have a structure of un-adsorbed molecules of the silicon-containing precursor 306 with a ligand or an H atom being dissociated.

Referring to FIGS. 3D and 6, in step 614, a second purge process is performed to remove un-adsorbed molecules of the silicon-containing precursor 306 (see FIG. 3C) from the deposition chamber 202. In certain embodiments, an inert gas (e.g., He, Ar, Xe, or the like) or N₂ may be introduced into the deposition chamber 202 to remove the un-adsorbed molecules of the silicon-containing precursor 306 (see FIG. 3C) from the deposition chamber 202.

Referring to FIGS. 3E and 6, in step 616, a nitrogen-containing precursor 310 is introduced into the deposition chamber 202 over the semiconductor structure 100. The nitrogen-containing precursor 310 may comprise a nitrogen-containing gas such as N₂, NH₃, or the like in vacuum or plasma environment. Molecules of the nitrogen-containing precursor 310 react with the adsorbed molecules 306′ of the silicon-containing precursor 306 that are present in the silicon-containing precursor layer 308 (see FIG. 3D) to form a dielectric layer 312 comprising silicon nitride. The inhibitor material layer 304 protects the dielectric layer 106 from nitridation due to the nitrogen-containing precursor 310.

Referring to FIGS. 3F and 6, in step 618, a third purge process is performed to remove unreacted molecules of the nitrogen-containing precursor 310 (see FIG. 3E) and volatile reaction byproducts from the deposition chamber 202. In certain embodiments, an inert gas (e.g., He, Ar, Xe, or the like) or N₂ may be introduced into the deposition chamber 202 to remove the unreacted molecules of the nitrogen-containing precursor 310 (see FIG. 3E) and the volatile reaction byproducts from the deposition chamber 202.

Referring to FIGS. 3G and 6, the deposition cycle described above with reference to steps 606 through 618 and FIGS. 3A through 3F, may be repeated one or more times until it is determined, in step 620, that a desired thickness H2 of the deposited dielectric layer 316 is achieved. In the illustrated embodiment, the deposited dielectric layer 316 comprises the dielectric layers 312 through 314, with the dielectric layer 314 being an uppermost dielectric layer of the deposited dielectric layer 316. The dielectric layers 312 through 314 may be also referred to as sub-layers of the deposited dielectric layer 316. In certain embodiments, molecules of the nitrogen-containing precursor 310 (see FIG. 3E) introduced into the deposition chamber 202 during various deposition cycles may react with molecules of the inhibitor material 302 (see FIG. 3A) that are present in the inhibitor material layer 304 (see FIG. 3F) to form a nitridated inhibitor material layer 318. In other embodiments, the inhibitor material layer 304 (see FIG. 3F) may remain un-nitridated.

Referring to FIGS. 3H and 6, in step 622, the un-nitridated inhibitor material layer 304 (see FIG. 3F) or the nitridated inhibitor material layer 318 (see FIG. 3G) is removed to expose the dielectric layer 106. In certain embodiments, the removal process may comprise one or more etching process, such as one or more wet etching processes, one or more dry etching processes, or the like. The one or more etching process may comprise one or more etchants that are selective to the un-nitridated inhibitor material of the un-nitridated inhibitor material layer 304 (see FIG. 3F) or the nitridated inhibitor material of the nitridated inhibitor material layer 318 (see FIG. 3G).

Modifications, additions, or omissions may be made to the systems, apparatuses, and methods described herein. The components of the systems and apparatuses may be integrated or separated. Moreover, the operations of the systems and apparatuses may be performed by more, fewer, or other components. The methods may include more, fewer, or other steps. Additionally, steps may be performed in any suitable order. Additionally, operations of the systems and apparatuses may be performed using any suitable logic. As used in this document, “each” refers to each member of a set or each member of a subset of a set.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. The use of any and all examples, or exemplary language (e.g., “such as”) provided herein, is intended merely to better explain the disclosure and does not pose a limitation on the scope of claims.

1. A method comprising:
forming a structure, wherein the structure comprises:
a first dielectric layer made of silicon oxide; and
a second dielectric layer made of silicon nitride; and
performing a selective deposition process for depositing a third dielectric layer made of silicon oxide on the first dielectric layer, wherein performing the selective deposition process comprises performing one or more deposition cycles, and wherein performing a deposition cycle comprises:
introducing a silicon-containing precursor over the structure, wherein the silicon-containing precursor comprises a siloxane material having a chemical formula SiₐH_{b}(CH₃)_{2a+1-b}—O—Si_{c}H_{d}(CH₃)_{2c+1-d}, where a, c=1 or 2, and b, d≤2a+1, and wherein molecules of the silicon-containing precursor are selectively adsorbed on an exposed surface of the first dielectric layer; and
introducing an oxygen-containing precursor over the structure, wherein molecules of the oxygen-containing precursor react with the molecules of the silicon-containing precursor to form a silicon oxide sub-layer of the third dielectric layer.

2. The method of claim 1, wherein performing the deposition cycle further comprises purging un-adsorbed molecules of the silicon-containing precursor.

3. The method of claim 1, wherein performing the deposition cycle further comprises purging unreacted molecules of the oxygen-containing precursor.

4. The method of claim 1, wherein performing the deposition cycle further comprises, before introducing the silicon-containing precursor over the structure:
introducing an inhibitor material over the structure, wherein molecules of the inhibitor material are selectively adsorbed on an exposed surface of the second dielectric layer.

5. The method of claim 4, wherein performing the deposition cycle further comprises purging un-adsorbed molecules of the inhibitor material.

6. The method of claim 4, wherein the inhibitor material comprises a material having a chemical formula CₐH_{b}X_{2a+2-b}, where a=1 or 2, b<2a+2, and X═Cl, Br, or I.

7. The method of claim 4, further comprising, after depositing the third dielectric layer, removing adsorbed molecules of the inhibitor material from the second dielectric layer.

8. The method of claim 1, wherein the oxygen-containing precursor comprises an oxygen-containing gas such as O₂, H₂O, or O₃.

9. The method of claim 1, wherein the exposed surface of the first dielectric layer is an OH-terminated surface.

10. The method of claim 1, wherein the exposed surface of the second dielectric layer is an NH₂-terminated surface.

11. A method comprising:
forming a structure, wherein the structure comprises:
a first dielectric layer made of silicon oxide; and
a second dielectric layer made of silicon nitride; and
performing a selective deposition process for depositing a third dielectric layer made of silicon nitride on the second dielectric layer, wherein performing the selective deposition process comprises performing one or more deposition cycles, and wherein performing a deposition cycle comprises:
introducing a silicon-containing precursor over the structure, wherein the silicon-containing precursor comprises a material having a chemical formula SiₐH_{b}X_{2a+2-b}, where a is 1 or 2, b<2a+2 and X═Br or I, and wherein molecules of the silicon-containing precursor are selectively adsorbed on an exposed surface of the second dielectric layer; and
introducing a nitrogen-containing precursor over the structure, wherein molecules of the nitrogen-containing precursor react with the molecules of the silicon-containing precursor to form a silicon nitride sub-layer of the third dielectric layer.

12. The method of claim 11, wherein performing the deposition cycle further comprises purging un-adsorbed molecules of the silicon-containing precursor.

13. The method of claim 11, wherein performing the deposition cycle further comprises purging unreacted molecules of the nitrogen-containing precursor.

14. The method of claim 11, wherein performing the deposition cycle further comprises, before introducing the silicon-containing precursor over the structure:
introducing an inhibitor material over the structure, wherein molecules of the inhibitor material are selectively adsorbed on an exposed surface of the first dielectric layer.

15. The method of claim 14, wherein performing the deposition cycle further comprises purging un-adsorbed molecules of the inhibitor material.

16. The method of claim 14, wherein the inhibitor material comprises a material having a chemical formula R₁—O—R₂, or R₁—NH₂, where R₁ is CH₃— or CH₃CH₂— and R₂ is CH₃— or CH₃CH₂—.

17. The method of claim 14, further comprising, after depositing the third dielectric layer, removing adsorbed molecules of the inhibitor material from the second dielectric layer.

18. The method of claim 11, wherein the nitrogen-containing precursor comprises a nitrogen-containing gas such as N₂ or NH₃.

19. The method of claim 11, wherein the exposed surface of the first dielectric layer is an OH-terminated surface.

20. The method of claim 11, wherein the exposed surface of the second dielectric layer is an NH₂-terminated surface.
